(19) United States
(12) Patent Application Publication
(10) Pub. No.: US 2026/0113013 A1
(43) Pub. Date: Apr. 23, 2026

(54) MULTILAYERED COMMON MODE FILTER

(71) Applicant: AMOTECH CO., LTD., Incheon (KR)

(72) Inventor: Byungguk LIM, Incheon (KR)

(73) Assignee: AMOTECH CO., LTD., Incheon (KR)

(21) Appl. No.: 19/116,217

(22) PCT Filed: Sep. 7, 2023
(86) PCT No.: PCT/KR2023/013380

§ 371 Date: Apr. 1, 2025

(30) Foreign Application Priority Data
Sep. 27, 2022 (KR) 10-2022-0122185

(51) Int. Cl. H03H 7/01; H01F 17/00

(52) U.S. Cl. CPC H03H 7/0115; H01F 17/0013; H01F 2017/0026

(57) ABSTRACT

Disclosed is a multilayered common mode filter exhibiting wideband characteristics as well as allowing uniform resistance and inductance in the coil patterns that form the channels. The disclosed multilayered common mode filter includes first and second capacitor layers on top and bottom, respectively, of an electrode stack, to overlap with multiple coil patterns and form additional capacitance, the electrode stack including stacked upper and lower electrode layers each having a stacked body provided with multiple coil patterns.

### TECHNICAL FIELD

Embodiments of the present disclosure relate to a multilayered common mode filter that allows differential mode signal current to pass therethrough in a C-PHY environment, which is a high-speed signal line supporting high-resolution image sensors and displays, and removes common mode noise current.

### BACKGROUND ART

In general, mobile terminals adopt the mobile industry processor interface (MIPI) D-PHY standard as a digital data transmission standard. The MIPI D-PHY standard is a digital data transmission standard that connects a main circuit and a display or a camera of the mobile terminal, and transmits data as a differential signal using two transmission lines.

As data transmitted/received in the mobile terminal rapidly increases, the mobile terminal requires a transmission method capable of transmitting/receiving data at a higher speed than the MIPI D-PHY.

Accordingly, recently, research is being conducted in the mobile terminal field to apply the MIPI C-PHY standard to mobile terminals. The MIPI C-PHY standard uses three transmission lines to perform differential output in such a way that a transmission side transmits different voltages to each transmission line and a reception side takes difference between the transmission lines.

The contents described in the Background Art are to help the understanding of the background of the disclosure, and may include contents that are not a disclosed conventional technology.

### DISCLOSURE

### Technical Problem

The present disclosure has been proposed in consideration of the aforementioned circumstances, and an object of the present disclosure is to provide a multilayered common mode filter exhibiting wideband characteristics by stacking a capacitor layer on the top and bottom of an electrode layer as well as allowing uniform resistance and inductance in coil patterns that form each channel.

### Technical Solution

A multilayered common mode filter according to embodiments of the present disclosure includes an upper electrode layer configured as a stacked body including a first coil pattern, a second coil pattern, and a third coil pattern, a lower electrode layer configured as a stacked body including a fourth coil pattern, a fifth coil pattern, and a sixth coil pattern and arranged on a bottom of the upper electrode layer, a first capacitor layer configured as a stacked body including a capacitor pattern and a ground pattern, arranged on a top of the upper electrode layer, and configured to overlap the first coil pattern to the sixth coil pattern to form an additional capacitance, and a second capacitor layer configured as a stacked body including a capacitor pattern and a ground pattern, arranged on a bottom of the lower electrode layer, and configured to overlap the first coil pattern to the sixth coil pattern to form an additional capacitance.

### Advantageous Effects

According to the present disclosure, the multilayered common mode filter can keep a distance (gap) between the coil patterns constituting each channel constant, thereby uniformly maintaining the resistance and inductance of the coil patterns constituting each channel. That is, the multilayered common mode filter can minimize changes in the inductance characteristics of the coil patterns by keeping a distance (gap) between the channels.

In addition, the multilayered common mode filter can minimize changes in the inductance characteristics and common mode attenuation characteristics of the coil patterns by disposing terminal patterns for connection with external electrodes at the top and bottom of an electrode stack.

In addition, in the multilayered common mode filter, the capacitor layer is arranged on the top and bottom of the electrode stack to form an additional notch in the common mode attenuation characteristics, thereby expanding an attenuation band.

In addition, in the multilayered common mode filter, the capacitor layer is arranged on the top and bottom of the electrode stack, so that an additional pole (i.e., additional capacitance) is formed by the capacitor layer and the coil pattern together with a pole formed by the coil patterns of the electrode stack. Accordingly, the multilayered common mode filter can exhibit wideband characteristics by forming a dual pole like an LC filter structure.

In addition, a parasitic inductor (parasitic L) is a major factor for forming a secondary resonance frequency of the common mode filter, and the parasitic inductor increases according to the mounting direction of a chip, so that a secondary resonance point may be changed. Accordingly, in the multilayered common mode filter, the capacitor layer is arranged on the top and bottom of the electrode stack to reduce the influence of the parasitic inductor (parasitic L) according to the mounting direction of the chip, thereby preventing the occurrence of characteristic deviation according to the mounting direction.

In addition, the multilayered common mode filter can adjust/control the secondary resonance point by adding or transforming the capacitor pattern of the capacitor layer.

In addition, the multilayered common mode filter can improve magnetic coupling (i.e., electromagnetic coupling) between the first coil to the third coil and minimize the degradation of a differential signal.

In addition, the multilayered common mode filter can form the electrode stack by stacking sheets formed with two or less via holes, thereby simplifying the manufacturing process.

That is, the multilayered common mode filter can minimize the number of via holes for connecting the coil patterns by disposing the terminal patterns at the top and bottom of the electrode stack, disposing the second coil pattern and the third coil pattern of a second channel between the first coil pattern and the sixth coil pattern of a first channel, and disposing the fourth coil pattern and the fifth coil pattern of a third channel between the third coil pattern and the sixth coil pattern, and two or less via holes are formed in each sheet.

### DESCRIPTION OF DRAWINGS

FIG. 1 is a perspective view of a multilayered common mode filter according to an embodiment of the present disclosure.

FIG. 2 is a perspective view for describing a filter stack in FIG. 1.

FIG. 3 is an exploded perspective view for describing an example of an upper electrode layer in FIG. 2.

FIGS. 4 to 7 are views for describing the upper electrode layer in FIG. 3.

FIG. 8 is an exploded perspective view for describing an example of a lower electrode layer in FIG. 2.

FIGS. 9 to 12 are views for describing the lower electrode layer in FIG. 8.

FIGS. 13 to 16 are exploded perspective views for describing a first capacitor layer and a second capacitor layer in FIG. 2.

FIG. 17 is an exploded perspective view for describing a modified example of the first capacitor layer and the second capacitor layer in FIG. 2.

FIG. 18 is a vertical cross-sectional view for describing the filter stack in FIG. 2.

FIG. 19 is a view illustrating an equivalent circuit of the multilayered common mode filter according to an embodiment of the present disclosure.

FIGS. 20 and 21 are views for describing attenuation characteristics of a multilayered common mode filter according to the related art.

FIGS. 22 and 23 are views for describing an example of adjusting a secondary resonance point by changing a capacitor pattern of the multilayered common mode filter according to an embodiment of the present disclosure.

### MODE FOR INVENTION

Hereinafter, preferred embodiments of the present disclosure are described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed “on” or “under” another layer “directly” or “with a third layer interposed between the two layers (indirectly)”. Furthermore, a criterion for the term “on or under each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

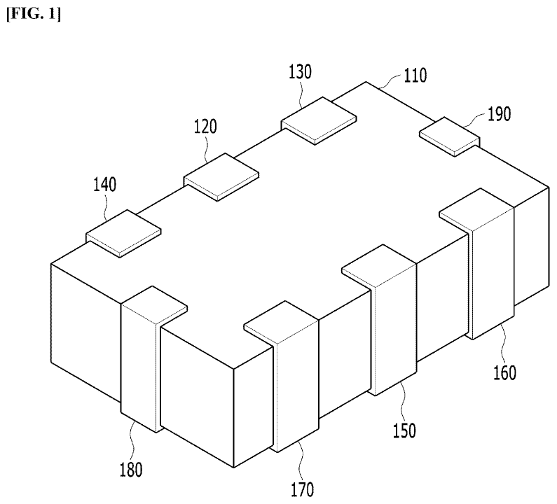

Referring to FIG. 1, a multilayered common mode filter according to an embodiment of the present disclosure includes a filter stack 110, a first external electrode 120, a second external electrode 130, a third external electrode 140, a fourth external electrode 150, a fifth external electrode 160, a sixth external electrode 170, a seventh external electrode 180, and an eighth external electrode 190. For example, the multilayered common mode filter operates as a three-channel C-PHY common mode filter.

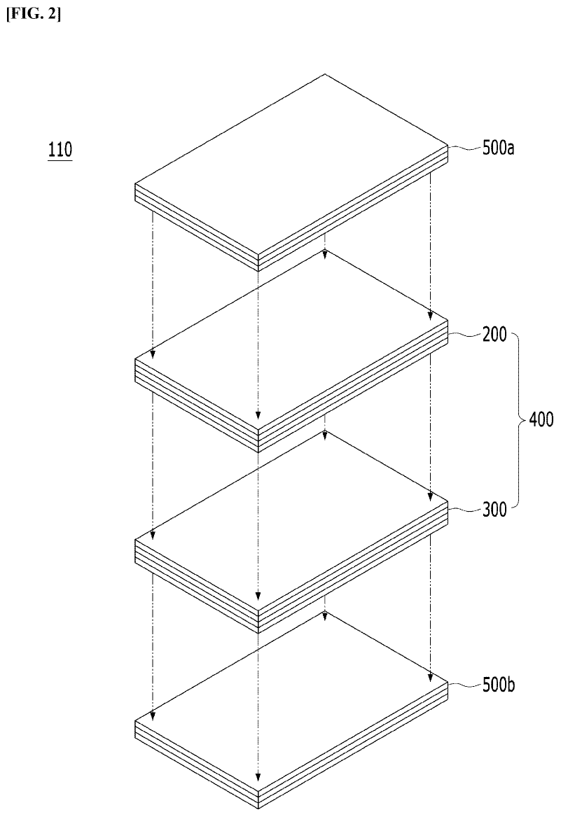

Referring to FIG. 2, the filter stack 110 is a stacked body in which an upper electrode layer 200, a lower electrode layer 300, a first capacitor layer 500a, and a second capacitor layer 500b are stacked.

The upper electrode layer 200 is configured as a stacked body in which a plurality of coil patterns are formed. In such a case, a magnetic layer made of ferrite, etc., may be further stacked on the top of the upper electrode layer 200.

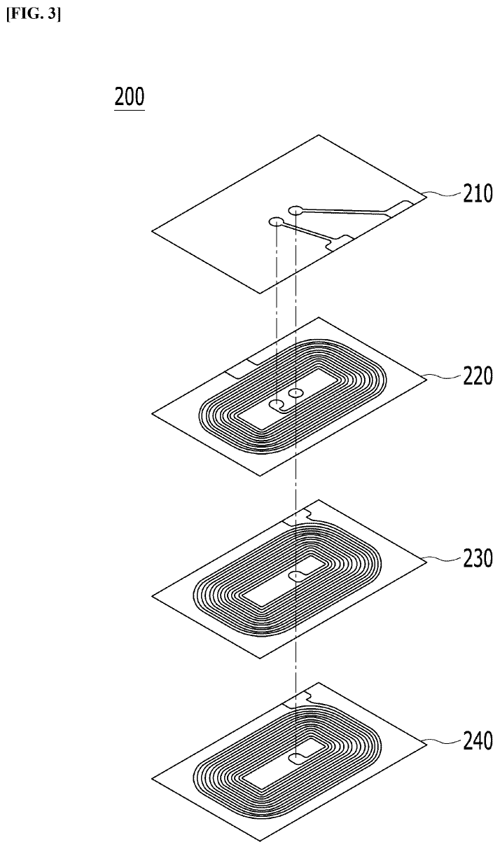

The upper electrode layer 200 is configured by stacking a plurality of sheets on which coil patterns are formed. For example, referring to FIG. 3, the upper electrode layer 200 includes a first sheet 210, a second sheet 220 arranged on the bottom of the first sheet 210, a third sheet 230 arranged on the bottom of the second sheet 220, and a fourth sheet 240 arranged on the bottom of the third sheet 230.

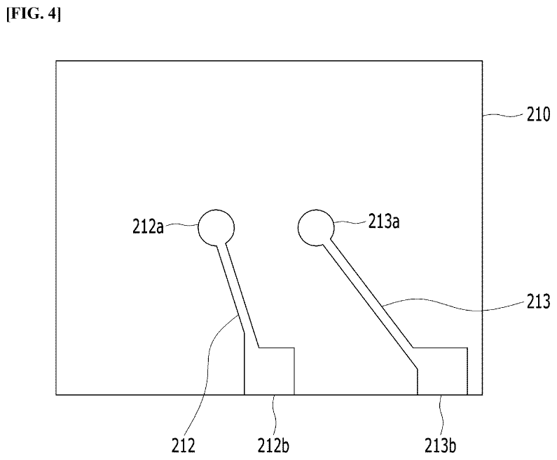

Referring to FIG. 4, a first terminal pattern 212 and a second terminal pattern 213 for connecting the coil patterns of the upper electrode layer 200 to an external electrode are arranged on the first sheet 210.

The first terminal pattern 212 is arranged on an upper surface of the first sheet 210. A first end 212a of the first terminal pattern 212 is arranged adjacent to the center of the first sheet 210. A second end 212b of the first terminal pattern 212 is arranged on the same line as a first side of the first sheet 210. Accordingly, the second end 212b of the first terminal pattern 212 is exposed to a first side of the filter stack 110.

The second terminal pattern 213 is arranged on the upper surface of the first sheet 210 to be spaced apart from the first terminal pattern 212. A first end 213a of the second terminal pattern 213 is arranged adjacent to the center of the first sheet 210. The first end 213a of the second terminal pattern 213 is arranged to be spaced apart from the first end 212a of the first terminal pattern 212. A second end 213b of the second terminal pattern 213 is arranged on the same line as the first side of the first sheet 210. The second end 213b of the second terminal pattern 213 is arranged adjacent to a fourth side of the first sheet 210 (i.e., a fourth side of the filter stack 110). Accordingly, the second end 213b of the second terminal pattern 213 is exposed to the first side of the filter stack 110 while being spaced apart from the second end 212b of the first terminal pattern 212.

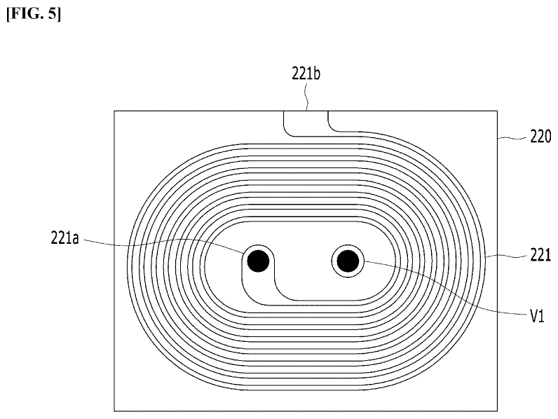

Referring to FIG. 5, the second sheet 220 is arranged on the bottom of the first sheet 210. The second sheet 220 is arranged with a first coil pattern 221 and a first via hole V1 that form a first channel.

The first coil pattern 221 is arranged on an upper surface of the second sheet 220. The first coil pattern 221 forms a first loop that is wound around the center of the second sheet 220 a plurality of times.

A first end 221a of the first coil pattern 221 is arranged adjacent to the center of the second sheet 220.

The first end 221a of the first coil pattern 221 is connected to the first end 212a of the first terminal pattern 212 through a via hole.

A second end 221b of the first coil pattern 221 is arranged on the same line as a second side of the second sheet 220. Accordingly, the second end 221b of the first coil pattern 221 is exposed to a second side of the filter stack 110. The second side of the filter stack 110 is a side opposite to the first side of the filter stack 110.

The first via hole V1 is arranged in an inner circumferential region of the first loop formed by the first coil pattern 221. The first via hole V1 is adjacent to the center of the second sheet 220 and is arranged to be spaced apart from the first end 221a of the first coil pattern 221. The first via hole V1 is formed to penetrate the second sheet 220. An upper portion of the first via hole V1 is connected to the second terminal pattern 213 through the via hole penetrating the first sheet 210. A lower portion of the first via hole V1 is connected to a coil pattern formed on the third sheet 230 to be described below.

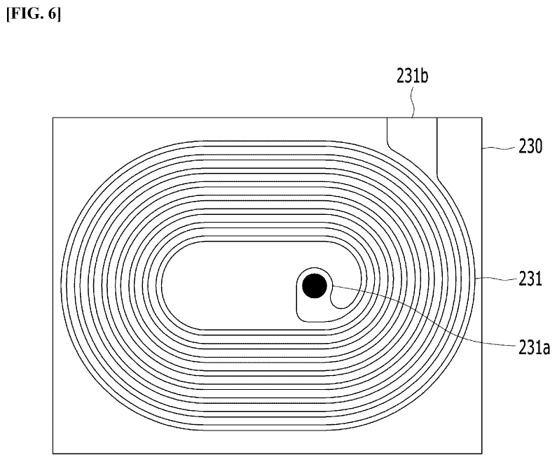

Referring to FIG. 6, the third sheet 230 is arranged on the bottom of the second sheet 220. The third sheet 230 is arranged with a second coil pattern 231 forming a second channel.

The second coil pattern 231 is arranged on an upper surface of the third sheet 230. The second coil pattern 231 forms a second loop that is wound around the center of the third sheet 230 a plurality of times.

A first end 231a of the second coil pattern 231 is arranged adjacent to the center of the third sheet 230. The first end 231a of the second coil pattern 231 is connected to the first end 213a of the second terminal pattern 213 through the first via hole V1 of the second sheet 220.

A second end 231b of the second coil pattern 231 is arranged on the same line as a second side of the third sheet 230. Accordingly, the second end 231b of the second coil pattern 231 is exposed to the second side of the filter stack 110.

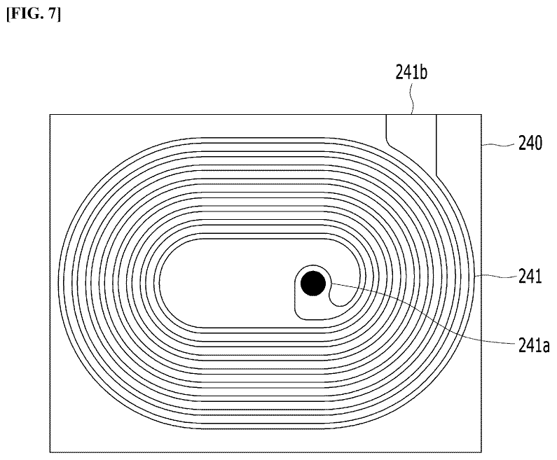

Referring to FIG. 7, the fourth sheet 240 is arranged on the bottom of the third sheet 230. The fourth sheet 240 is arranged with a third coil pattern 241 forming the second channel together with the second coil pattern 231.

The third coil pattern 241 is arranged on an upper surface of the fourth sheet 240. The fourth coil pattern 311 forms a third loop that is wound around the center of the fourth sheet 240 a plurality of times.

A first end 241a of the third coil pattern 241 is arranged adjacent to the center of the fourth sheet 240. The first end 241a of the third coil pattern 241 is connected to the first end 231a of the second coil pattern 231 and the first end 213a of the second terminal pattern 213 through the first via hole V1. Accordingly, the third coil pattern 241 forms a coil of the second channel together with the second coil pattern 231.

A second end 241b of the third coil pattern 241 is arranged on the same line as the second side of the fourth sheet 240. Accordingly, the second end of the third coil pattern is exposed to the second side of the filter stack 110.

The coil patterns and terminal patterns formed on the sheets forming the upper electrode layer 200 can be transformed into various shapes. The upper electrode layer 200 can be transformed into various shapes in the shape of the loop formed by the coil pattern, the position where the end is exposed, etc.

However, the order in which the first terminal pattern 212, the second terminal pattern 213, the first coil pattern 221, the second coil pattern 231, and the third coil pattern 241 are stacked in the upper electrode layer 200 maintains the order illustrated in the drawing.

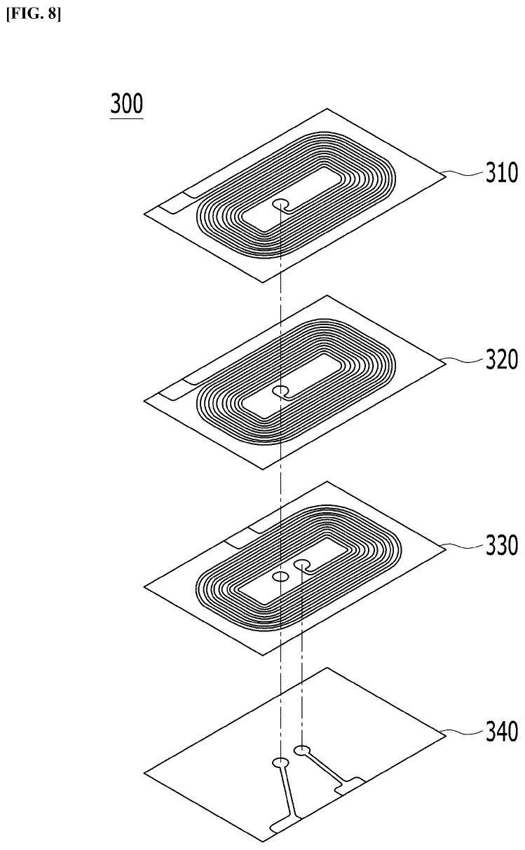

The lower electrode layer 300 is configured as a stacked body in which a plurality of coil patterns are formed, and is arranged on the bottom of the upper electrode layer 200. The lower electrode layer 300 is formed by stacking a plurality of sheets on which coil patterns are formed. For example, referring to FIG. 8, the lower electrode layer 300 includes a fifth sheet 310, a sixth sheet 320 arranged on the bottom of the fifth sheet 310, a seventh sheet 330 arranged on the bottom of the sixth sheet 320, and an eighth sheet 340 arranged on the bottom of the seventh sheet 330.

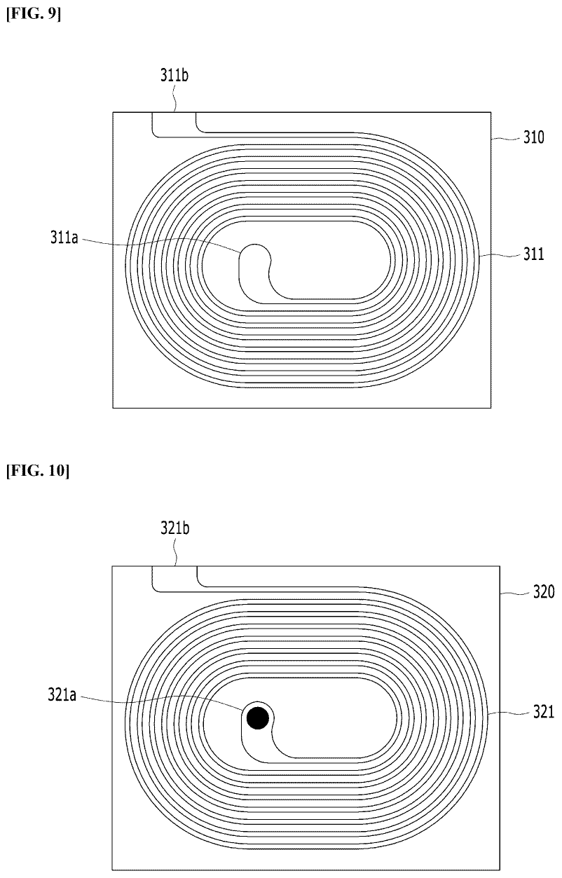

Referring to FIG. 9, the fifth sheet 310 is arranged on the bottom of the fourth sheet 240. The fifth sheet 310 is arranged with a fourth coil pattern 311 forming a third channel.

The fourth coil pattern 311 is arranged on an upper surface of the fifth sheet 310. The fourth coil pattern 311 forms a fourth loop that is wound around the center of the fifth sheet 310 a plurality of times.

A first end 311a of the fourth coil pattern 311 is arranged adjacent to the center of the fifth sheet 310.

A second end 311b of the fourth coil pattern 311 is arranged on the same line as a second side of the fifth sheet 310. Accordingly, the second end 311b of the fourth coil pattern 311 is exposed to the second side of the filter stack 110.

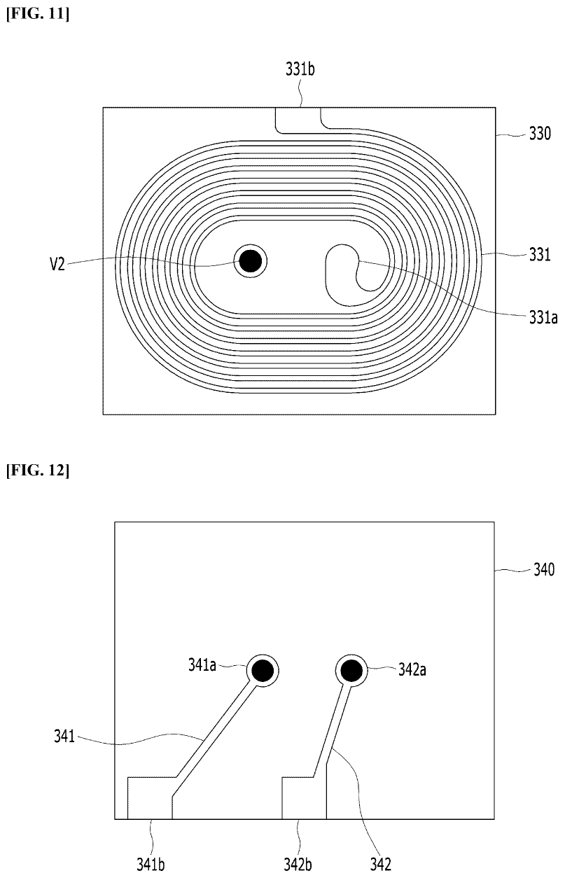

Referring to FIG. 10, the sixth sheet 320 is arranged on the bottom of the fifth sheet 310. The sixth sheet 320 is arranged with a fifth coil pattern 321 forming a third channel together with the fourth coil pattern 311.

The fifth coil pattern 321 is arranged on an upper surface of the sixth sheet 320. The fifth coil pattern 321 forms a fifth loop that is wound around the center of the sixth sheet 320 a plurality of times.

A first end 321a of the fifth coil pattern 321 is arranged adjacent to the center of the sixth sheet 320. The first end 321a of the fifth coil pattern 321 is connected to the first end 311a of the fourth coil pattern 311 through a via hole penetrating the fifth sheet 310.

A second end 321b of the fifth coil pattern 321 is arranged on the same line as the second side of the sixth sheet 320. Accordingly, the second end 321b of the fifth coil pattern 321 is exposed to the second side of the filter stack 110.

Referring to FIG. 11, the seventh sheet 330 is arranged on the bottom of the sixth sheet 320. The seventh sheet 330 is arranged with a sixth coil pattern 331 and a second via hole V2 that form the first channel together with the first coil pattern 221.

The sixth coil pattern 331 is arranged on an upper surface of the seventh sheet 330. The sixth coil pattern 331 forms a sixth loop that is wound around the center of the seventh sheet 330 a plurality of times.

A first end 331a of the sixth coil pattern 331 is arranged adjacent to the center of the seventh sheet 330. A second end 331b of the sixth coil pattern 331 is arranged on the same line as a second side of the seventh sheet 330. Accordingly, the second end 331b of the sixth coil pattern 331 is exposed to the second side of the filter stack 110.

The second via hole V2 is arranged in an inner circumferential region of the sixth loop formed by the sixth coil pattern 331. The second via hole V2 is arranged adjacent to the center of the seventh sheet 330 and spaced apart from the first end 331a of the sixth coil pattern 331. The second via hole V2 is formed to penetrate the seventh sheet 330. An upper portion of the second via hole V2 is connected to the fifth coil pattern 321 and the sixth coil pattern 331. A lower portion of the second via hole V2 is connected to a terminal pattern formed on the eighth sheet 340 to be described below.

Referring to FIG. 12, the eighth sheet 340 is arranged with a third terminal pattern 341 and a fourth terminal pattern 342 for connecting the coil pattern of the lower electrode layer 300 to an external electrode.

The third terminal pattern 341 is arranged on an upper surface of the eighth sheet 340. A first end 341a of the third terminal pattern 341 is arranged adjacent to the center of the eighth sheet 340. The first end 341a of the third terminal pattern 341 is connected to the first end 311a of the fourth coil pattern 311 and the first end 321a of the fifth coil pattern 321 through the second via hole V2. A second end 341b of the third terminal pattern 341 is arranged on the same line as a first side of the eighth sheet 340. Accordingly, the second end 341b of the third terminal pattern 341 is exposed to the first side of the filter stack 110.

The fourth terminal pattern 342 is arranged on the upper surface of the eighth sheet 340 to be spaced apart from the third terminal pattern 341. A first end 342a of the fourth terminal pattern 342 is arranged adjacent to the center of the eighth sheet 340. The first end 342a of the fourth terminal pattern 342 is connected to the first end 331a of the sixth coil pattern 331 through a via hole. A second end 342b of the fourth terminal pattern 342 is arranged on the same line as the first side of the eighth sheet 340. Accordingly, the second end 342b of the fourth terminal pattern 342 is exposed to the first side of the filter stack 110 while being spaced apart from the second end 341b of the third terminal pattern 341.

The coil patterns and terminal patterns formed on the sheets forming the lower electrode layer 300 can be transformed into various shapes. The lower electrode layer 300 can be transformed into various shapes in the shape of the loop formed by the coil pattern, the position where the end is exposed, etc. However, the order in which the fourth coil pattern 311, the fifth coil pattern 321, the sixth coil pattern 331, the third terminal pattern 341, and the fourth terminal pattern 342 are stacked in the lower electrode layer 300 maintains the order illustrated in the drawing.

The upper electrode layer 200 and the lower electrode layer 300 constitute an electrode stack 400. The electrode stack 400 is configured so that the first coil pattern 221, the second coil pattern 231, the third coil pattern 241, the fourth coil pattern 311, the fifth coil pattern 321, and the sixth coil pattern 331 are sequentially stacked. In such a case, the first coil pattern 221 and the sixth coil pattern 331 form a first coil constituting the first channel, the second coil pattern 231 and the third coil pattern 241 form a second coil constituting the second channel, and the fourth coil pattern 311 and the fifth coil pattern 321 form a third coil constituting the third channel.

Therefore, in the electrode stack 400, the coil pattern of the first channel, the coil pattern of the second channel, the coil pattern of the second channel, the coil pattern of the third channel, the coil pattern of the third channel, and the coil pattern of the first channel are sequentially arranged.

Through this, the multilayered common mode filter according to the embodiment of the present disclosure can keep the distance (gap) between the coil patterns constituting each channel constant, so that uniform resistance and inductance in the coil patterns that form each channel can be maintained.

In addition, the multilayered common mode filter according to the embodiment of the present disclosure can minimize changes in the inductance characteristics and common mode attenuation characteristics of the coil patterns by disposing terminal patterns for connection with external electrodes at the top and bottom of the electrode stack 400. In such a case, when the terminal pattern is arranged at only one of the top and bottom, since the inductance characteristics of each channel are changed or the inductance characteristics of each coil pattern are changed, the common mode attenuation characteristics are changed.

In addition, the multilayered common mode filter according to the embodiment of the present disclosure can minimize the number of via holes for connecting the coil patterns by disposing terminal patterns at the top and bottom of the electrode stack 400, disposing the second coil pattern 231 and the third coil pattern 241 of the second channel between the first coil pattern 221 and the sixth coil pattern 331 of the first channel, and disposing the fourth coil pattern 311 and the fifth coil pattern 321 of the third channel between the third coil pattern 241 and the sixth coil pattern 331. In such a case, in the multilayered common mode filter according to the embodiment of the present disclosure, two or less via holes are formed in each sheet.

The first capacitor layer 500a is configured as a stacked body in which a ground pattern and a plurality of capacitor patterns are formed. The first capacitor layer 500a is arranged on the upper electrode layer 200. In such a case, the first capacitor layer 500a may be stacked on the upper electrode layer 200 with a magnetic layer made of ferrite, etc., interposed between the first capacitor layer 500a and the upper electrode layer 200. A magnetic layer made of ferrite, etc., may be further stacked on the first capacitor layer 500a.

The second capacitor layer 500b is configured as a stacked body in which a ground pattern and a plurality of capacitor patterns are formed. The second capacitor layer 500b is arranged on the bottom of the lower electrode layer 300. In such a case, the second capacitor layer 500b may be stacked on the bottom of the lower electrode layer 300 with a magnetic layer made of ferrite, etc., interposed between the second capacitor layer 500b and the lower electrode layer 300. A magnetic layer made of ferrite, etc., may be further stacked on the bottom of the second capacitor layer 500b.

In such a case, by differently forming the areas of the capacitor patterns included in the capacitance layer 500 (i.e., the first capacitor layer 500a and/or the second capacitor layer 500b), a multilayered common mode filter having a high capacitance High Cp or a low capacitance Low Cp can be configured. The multilayered common mode filter has relatively high capacitance (High Cp) characteristics when the area of the capacitor pattern is widened, and has relatively low capacitance (Low Cp) characteristics when the area of the capacitor pattern is narrowed.

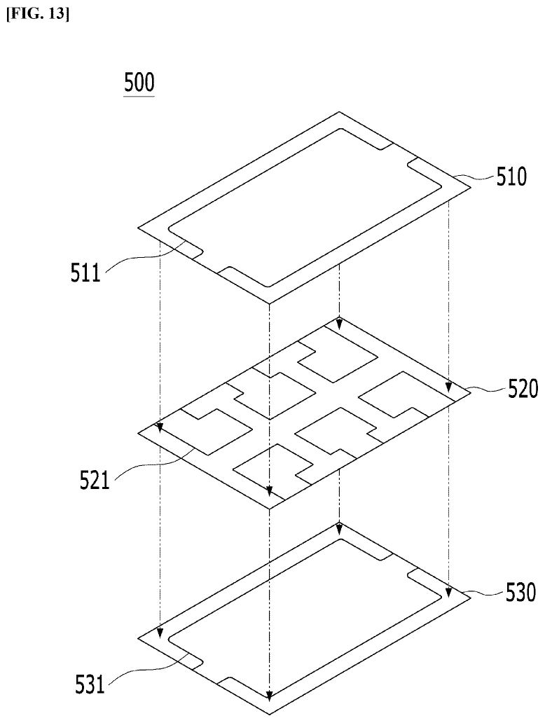

For example, referring to FIG. 13, the capacitor layer 500 is configured by stacking a ninth sheet 510, a tenth sheet 520, and an eleventh sheet 530.

A first ground pattern 511 is arranged on the ninth sheet 510. The first ground pattern 511 is arranged on an upper surface of the ninth sheet 510.

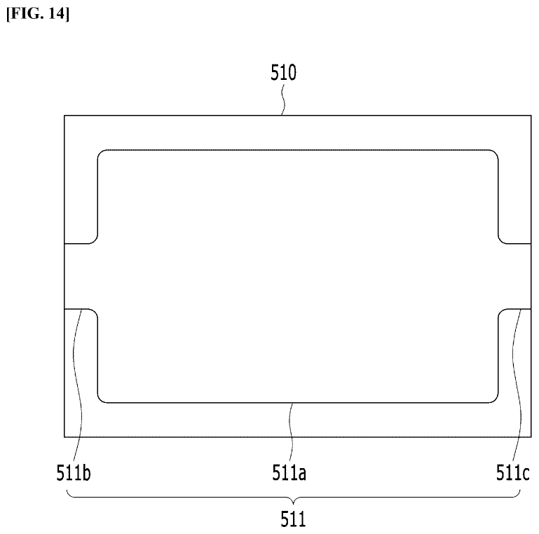

Referring to FIG. 14, the first ground pattern 511 may include a first pattern 511a, a second pattern 511b, and a third pattern 511c.

The first pattern 511a is formed in a plate shape and is arranged at the center of the upper surface of the ninth sheet 510. The first pattern 511a may be configured as an island pattern spaced apart from four sides of the ninth sheet 510.

The second pattern 511b extends from a third side of the first pattern 511a and is arranged on the same line as the third side of the ninth sheet 510. That is, a first end of the second pattern 511b is connected to a third side of the first pattern 511a. A second end of the second pattern 511b is arranged on the same line as the third side of the ninth sheet 510 and is exposed to a third side of the filter stack 110.

The third pattern 511c is arranged to face the second pattern 511b with the first pattern 511a interposed therebetween. The third pattern 511c extends from a fourth side of the first pattern 511a and is arranged on the same line as a fourth side of the ninth sheet 510. That is, a first end of the third pattern 511c is connected to the fourth side of the first pattern 511a. A second end of the third pattern 511c is arranged on the same line as the fourth side of the ninth sheet 510 and is exposed to a fourth side of the filter stack 110.

Accordingly, the first ground pattern 511 is exposed to the third side and the fourth side of the filter stack 110.

The tenth sheet 520 is arranged on the bottom of the ninth sheet 510. A capacitor pattern 521 is arranged on an upper surface of the tenth sheet 520.

The capacitor pattern 521 is arranged to overlap the coil pattern included in the electrode stack 400. The capacitor pattern 521 forms a capacitance together with the coil pattern. Through this, the capacitor pattern 521 forms an additional notch in the common mode attenuation characteristics to expand an attenuation band, so that the multilayered common mode filter has wideband characteristics with an attenuation band between approximately 1 GHz and 10 GHz.

The capacitor pattern 521 includes a plurality of capacitor patterns arranged at input and output terminals of the multilayered common mode filter.

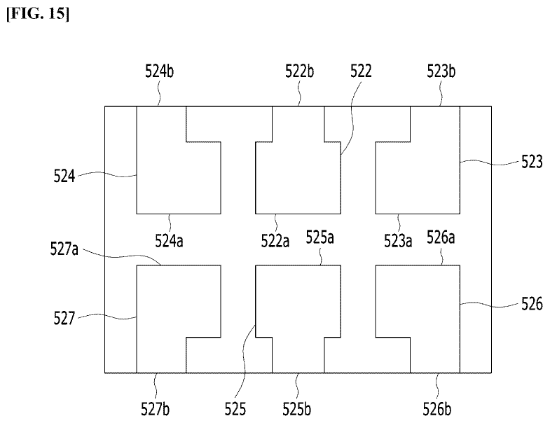

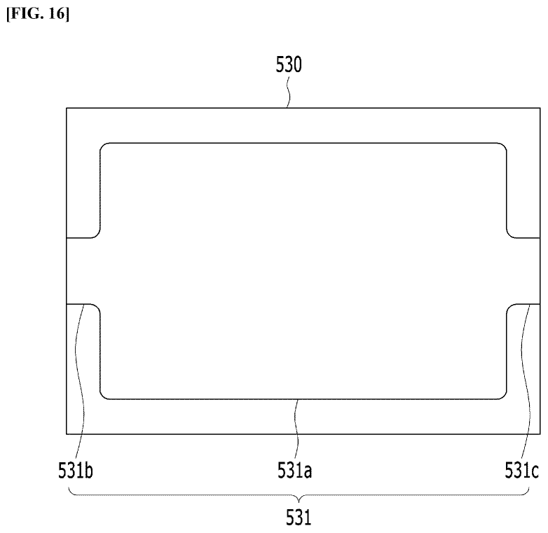

For example, referring to FIG. 15, the capacitor pattern 521 includes a first capacitor pattern 522, a second capacitor pattern 523, a third capacitor pattern 524, a fourth capacitor pattern 525, a fifth capacitor pattern 526, and a sixth capacitor pattern 527.

As an example, the first capacitor pattern 522 to the third capacitor pattern 524 operate as the input terminals of the multilayered common mode filter, and the fourth capacitor pattern 525 to the sixth capacitor pattern 527 operate as the output terminals of the multilayered common mode filter. The first capacitor pattern 522 to the third capacitor pattern 524 may operate as the output terminals of the multilayered common mode filter, and the fourth capacitor pattern 525 to the sixth capacitor pattern 527 may operate as the input terminals of the multilayered common mode filter.

The first capacitor pattern 522 is arranged on an upper surface of the tenth sheet 520.

A first end 522a of the first capacitor pattern 522 is arranged adjacent to the center of the tenth sheet 520. A second end 522b of the first capacitor pattern 522 is arranged on the same line as a second side of the tenth sheet 520. Accordingly, the first capacitor pattern 522 is exposed to the second side of the filter stack 110.

The second capacitor pattern 523 is arranged on the upper surface of the tenth sheet 520 to be spaced apart from the first capacitor pattern 522. The second capacitor pattern 523 is arranged adjacent to a fourth side of the tenth sheet 520.

A first end 523a of the second capacitor pattern 523 is arranged adjacent to the center of the tenth sheet 520. The second end 523b of the second capacitor pattern 523 is arranged on the same line as the second side of the tenth sheet 520. Accordingly, the second capacitor pattern 523 is exposed to the second side of the filter stack 110.

The third capacitor pattern 524 is arranged on the upper surface of the tenth sheet 520. The third capacitor pattern 524 is arranged on the upper surface of the tenth sheet 520 to be spaced apart from the first capacitor pattern 522 and the second capacitor pattern 523. The third capacitor pattern 524 is arranged adjacent to a third side of the tenth sheet 520 and faces the second capacitor pattern 523 with the first capacitor pattern 522 interposed therebetween.

A first end 524a of the third capacitor pattern 524 is arranged adjacent to the center of the tenth sheet 520. A second end 524b of the third capacitor pattern 524 is arranged on the same line as the second side of the tenth sheet 520. Accordingly, the third capacitor pattern 524 is exposed to the second side of the filter stack 110.

The fourth capacitor pattern 525 is arranged on the upper surface of the tenth sheet 520. The fourth capacitor pattern 525 is arranged to face the first capacitor pattern 522.

A first end 525a of the fourth capacitor pattern 525 is arranged adjacent to the center of the tenth sheet 520 and faces the first end 522a of the first capacitor pattern 522. A second end 525b of the fourth capacitor pattern 525 is arranged on the same line as a first side of the tenth sheet 520. Accordingly, the fourth capacitor pattern 525 is exposed to the first side of the filter stack 110.

The fifth capacitor pattern 526 is arranged on the upper surface of the tenth sheet 520 to be spaced apart from the fourth capacitor pattern 525. The fifth capacitor pattern 526 is arranged adjacent to the fourth side of the tenth sheet 520. The fifth capacitor pattern 526 is arranged to face the second capacitor pattern 523.

A first end 526a of the fifth capacitor pattern 526 is arranged adjacent to the center of the tenth sheet 520 and faces the first end 523a of the second capacitor pattern 523. A second end 526b of the fifth capacitor pattern 526 is arranged on the same line as the first side of the tenth sheet 520. Accordingly, the fifth capacitor pattern 526 is exposed to the first side of the filter stack 110.

The sixth capacitor pattern 527 is arranged on the upper surface of the tenth sheet 520 to be spaced apart from the fourth capacitor pattern 525 and the fifth capacitor pattern 526. The sixth capacitor pattern 527 is arranged adjacent to the third side of the tenth sheet 520 and faces the third capacitor pattern 524. In such a case, the sixth capacitor pattern 527 is arranged to face the fifth capacitor pattern 526 with the fourth capacitor pattern 525 interposed therebetween.

A first end 527a of the sixth capacitor pattern 527 is arranged adjacent to the center of the tenth sheet 520 and faces the first end 524a of the third capacitor pattern 524. A second end 527b of the sixth capacitor pattern 527 is arranged on the same line as the first side of the tenth sheet 520. Accordingly, the sixth capacitor pattern 527 is exposed to the first side of the filter stack 110.

The capacitor pattern 521 may include a plurality of patterns (i.e., the first capacitor pattern 522 to the third capacitor pattern 524) arranged at the input terminals of the multilayered common mode filter, or may include a plurality of patterns (i.e., the fourth capacitor pattern 525 to the sixth capacitor pattern 527 arranged at the output terminal of the multilayered common mode filter.

The eleventh sheet 530 is arranged on the bottom of the tenth sheet 520. The eleventh sheet 530 is arranged with a second ground pattern 531.

Referring to FIG. 16, the second ground pattern 531 is arranged on an upper surface of the eleventh sheet 530. The second ground pattern 531 may include a fourth pattern 531a, a fifth pattern 531b, and a sixth pattern 531c.

The fourth pattern 531a is formed in a plate shape and arranged at the center of the upper surface of the eleventh sheet 530. The fourth pattern 531a may be configured as an island pattern spaced apart from four sides of the eleventh sheet 530.

The fifth pattern 531b extends from a third side of the fourth pattern 531a and is arranged on the same line as a third side of the eleventh sheet 530. That is, a first end of the fifth pattern 531b is connected to the third side of the fourth pattern 531a. A second end of the fifth pattern 531b is arranged on the same line as the third side of the eleventh sheet 530 and is exposed to the third side of the filter stack 110.

The sixth pattern 531c is arranged to face the fifth pattern 531b with the fourth pattern 531a interposed therebetween. The sixth pattern 531c extends from a fourth side of the fourth pattern 531a and is arranged on the same line as a fourth side of the eleventh sheet 530. That is, a first end of the sixth pattern 531c is connected to the fourth side of the fourth pattern 531a. A second end of the sixth pattern 531c is arranged on the same line as the fourth side of the eleventh sheet 530 and is exposed to the fourth side of the filter stack 110.

Accordingly, the second ground pattern 531 is exposed to the third side and the fourth side of the filter stack 110.

In order to adjust the position of an additional pole, the capacitor layer 500 may further include a sheet on which a ground pattern is formed and a sheet on which a capacitor pattern is formed.

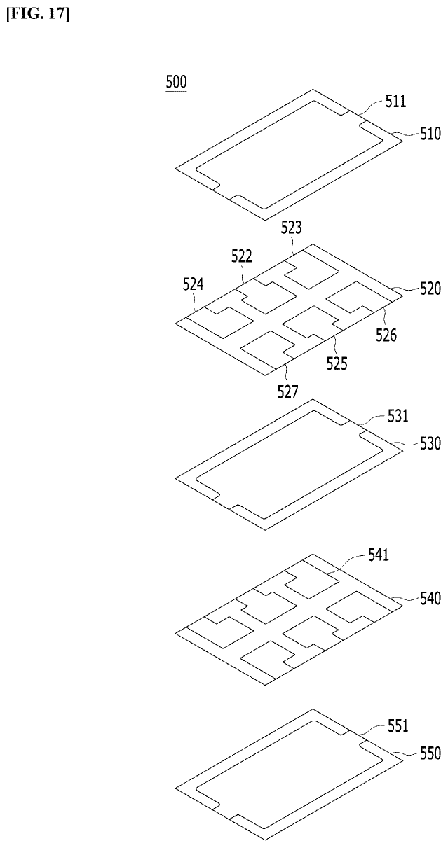

For example, referring to FIG. 17, the capacitor layer 500 may further include a twelfth sheet 540 on which a plurality of capacitor patterns 541 are arranged and a thirteenth sheet 550 on which a third ground pattern 551 is arranged. In such a case, since the position of the additional pole in the multilayered common mode filter is adjusted by the capacitance, the number of capacitor patterns and ground patterns to be added may vary.

The first external electrode 120 is arranged on the second side of the filter stack 110. The first external electrode 120 is connected to the second end 221b of the first coil pattern 221 and the second end 331b of the sixth coil pattern 331 that are exposed to the second side of the filter stack 110. The first external electrode 120 is also connected to the second end 522b of the first capacitor pattern 522 exposed to the second side of the filter stack 110. Both ends of the first external electrode 120 may be formed to extend to the upper and lower surfaces of the filter stack 110.

The second external electrode 130 is arranged on the second side of the filter stack 110. The second external electrode 130 is spaced apart from the first external electrode 120 and is arranged adjacent to the fourth side of the filter stack 110. The second external electrode 130 is connected to the second end 231b of the second coil pattern 231 and the second end 241b of the third coil pattern 241 that are exposed to the second side of the filter stack 110. The second external electrode 130 is also connected to the second end 523b of the second capacitor pattern 523 exposed to the second side of the filter stack 110. Both ends of the second external electrode 130 may be formed to extend to the upper and lower surfaces of the filter stack 110.

The third external electrode 140 is arranged on the second side of the filter stack 110. The third external electrode 140 is spaced apart from the first external electrode 120 and is arranged adjacent to the third side of the filter stack 110. The third external electrode 140 faces the second external electrode 130 with the first external electrode 120 interposed therebetween, and the first external electrode 120 is interposed between the second external electrode 130 and the third external electrode 140.

The third external electrode 140 is connected to the second end 311b of the fourth coil pattern 311 and the second end 321b of the fifth coil pattern 321 that are exposed to the second side of the filter stack 110. The third external electrode 140 is also connected to the second end 524b of the third capacitor pattern 524 exposed to the second side of the filter stack 110. Both ends of the third external electrode 140 can be formed to extend to the upper and lower surfaces of the filter stack 110.

The fourth external electrode 150 is arranged on the first side of the filter stack 110. The fourth external electrode 150 faces the first external electrode 120 with the filter stack 110 interposed therebetween. The fourth external electrode 150 is connected to the second end 212b of the first terminal pattern 212 and the second end 342b of the fourth terminal pattern 342 that are exposed to the first side of the filter stack 110. The fourth external electrode 150 is also connected to the second end 525b of the fourth capacitor pattern 525 exposed to the first side of the filter stack 110. Both ends of the fourth external electrode 150 may be formed to extend to the upper and lower surfaces of the filter stack 110.

The fifth external electrode 160 is arranged on the first side of the filter stack 110. The fifth external electrode 160 is spaced apart from the fifth external electrode 160 and is arranged adjacent to the fourth side of the filter stack 110. The fifth external electrode 160 faces the second external electrode 130 with the filter stack 110 interposed therebetween. The fifth external electrode 160 is connected to the second end 213b of the second terminal pattern 213 exposed to the first side of the filter stack 110. The fifth external electrode 160 is also connected to the second end 526b of the fifth capacitor pattern 526 exposed to the first side of the filter stack 110. Both ends of the fifth external electrode 160 may be formed to extend to the upper and lower surfaces of the filter stack 110.

The sixth external electrode 170 is arranged on the first side of the filter stack 110. The sixth external electrode 170 is spaced apart from the fourth external electrode 150 and the fifth external electrode 160, and is arranged adjacent to the third side of the filter stack 110. The sixth external electrode 170 faces the third external electrode 140 with the filter stack 110 interposed therebetween. The sixth external electrode 170 faces the fifth external electrode 160 with the fourth external electrode 150 interposed therebetween, and the fourth external electrode 150 is interposed between the fifth external electrode 160 and the sixth external electrode 170. The sixth external electrode 170 is connected to the second end 341b of the third terminal pattern 341 exposed to the first side of the filter stack 110. The sixth external electrode 170 is also connected to the second end 527b of the sixth capacitor pattern 527 exposed to the first side of the filter stack 110. Both ends of the sixth external electrode 170 may be formed to extend to the upper and lower surfaces of the filter stack 110.

The seventh external electrode 180 is arranged on the third side of the filter stack 110. The seventh external electrode 180 is connected to the first ends of the ground patterns 511 and 531. Both ends of the seventh external electrode 180 may be formed to extend to the upper and lower surfaces of the filter stack 110.

The eighth external electrode 190 is arranged on the fourth side of the filter stack 110. The eighth external electrode 190 faces the seventh external electrode 180 with the filter stack 110 interposed therebetween. The eighth external electrode 190 is connected to the second ends of the ground patterns 511 and 531. Both ends of the eighth external electrode 190 may be formed to extend to the upper and lower surfaces of the filter stack 110.

The first external electrode 120 and the fourth external electrode 150 operate as input terminals and output terminals of the first channel configured by the first terminal pattern 212, the first coil pattern 221, the sixth coil pattern 331, and the fourth terminal pattern 342.

The second external electrode 130 and the sixth external electrode 170 operate as input terminals and output terminals of the second channel configured by the second coil pattern 231, the third coil pattern 241, and the second terminal pattern 213.

The third external electrode 140 and the fifth external electrode 160 operate as input terminals and output terminals of the third channel formed by the fourth coil pattern 311, the fifth coil pattern 321, and the third terminal pattern 341.

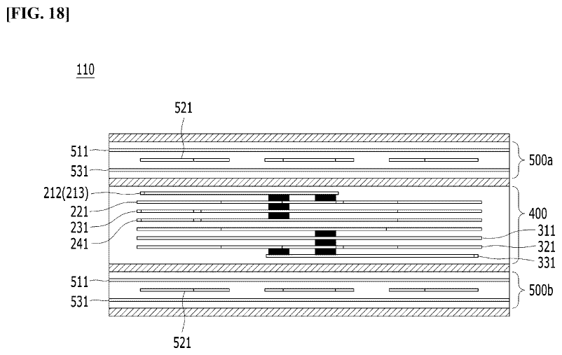

Referring to FIG. 18, the multilayered common mode filter according to the embodiment of the present disclosure includes six coil patterns forming three channels.

The first coil pattern 221 and the sixth coil pattern 331 form a first coil forming the first channel and are interposed between the terminal patterns arranged at the top and bottom of the electrode stack 400, respectively. The second coil pattern 231 and the third coil pattern 241 are interposed between the first coil pattern 221 and the sixth coil pattern 331 to form a second coil forming the third channel. The fourth coil pattern 311 and the fifth coil pattern 321 are interposed between the third coil pattern 241 and the sixth coil pattern 331 to form a third coil that constitutes the third channel.

Through this, the multilayered common mode filter can minimize changes in the inductance characteristics of the coil patterns by configuring the distance (gap) between the channels to be constant.

In addition, in the multilayered common mode filter, since the terminal patterns for connecting the coil patterns to the external electrodes are arranged at the top and bottom of the electrode stack 400, the distance between the coil patterns and the terminal patterns can be configured to be the same for each channel, so that uniform resistance and inductance in the coil patterns that form each channel can be formed.

The multilayered common mode filter according to the embodiment of the present disclosure can improve magnetic coupling (i.e., electromagnetic coupling) between the first coil to the third coil and minimize the deterioration of a differential signal.

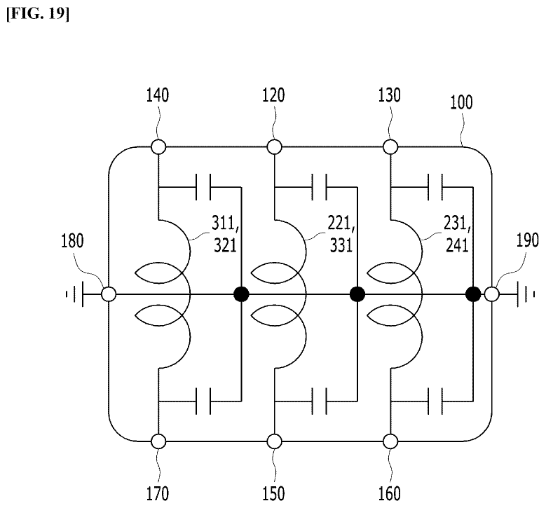

Referring to FIG. 19, in the multilayered common mode filter according to the embodiment of the present disclosure, a capacitance is formed between the first coil and the second coil, between the second coil and the third coil, and between the first coil and the third coil. In such a case, as the first capacitor layer 500a and the second capacitor layer 500b are arranged on the top and bottom of the electrode stack 400 including the upper electrode layer 200 and the lower electrode layer 300, respectively, a coupling effect occurs between the coil and the capacitor pattern 521, so that a capacitance is additionally formed between the coil and the capacitor pattern 521.

In this way, in the multilayered common mode filter according to the embodiment of the present disclosure, since an additional capacitance is formed between each coil and the capacitor pattern 521, a capacitance can be increased without adding an electrode layer including a sheet layer on which a coil pattern is formed.

In addition, in the multilayered common mode filter according to the embodiment of the present disclosure, as an additional capacitance is formed between the coil and the capacitor pattern 521, an additional notch can be formed in common mode attenuation characteristics to expand an attenuation band.

In general, in a multilayered common mode filter having an LC filter structure, a secondary resonance point is formed by an equivalent series inductance (ESL) of a parallel capacitance formed between a coil pattern and a capacitor pattern.

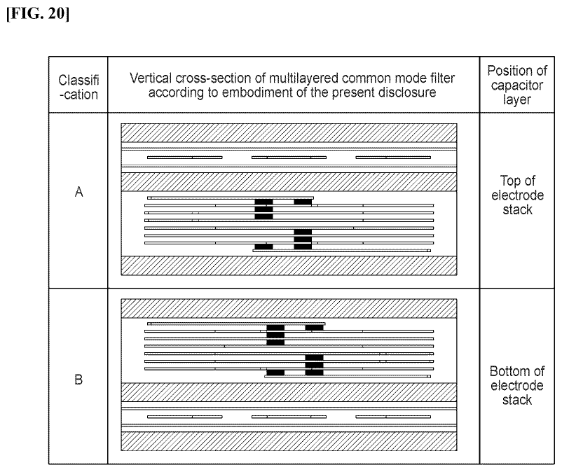

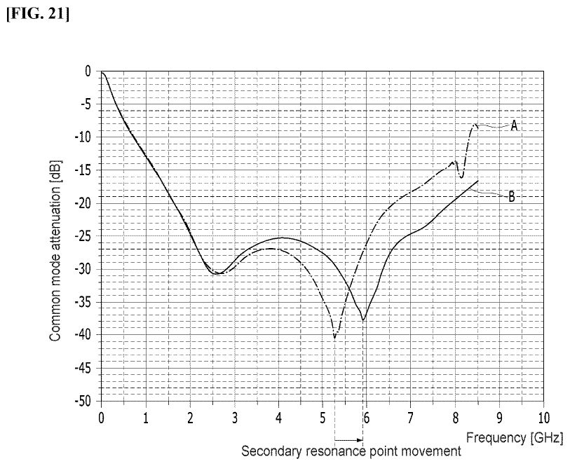

Referring to FIGS. 20 and 21, a multilayered common mode filter according to the related art is formed in an LC filter structure A in which a capacitor layer is arranged on the top of an electrode stack, or as an LC filter structure B in which a capacitor layer is arranged on the bottom of the electrode stack. In the multilayered common mode filter according to the related art, an equivalent series inductance of a parallel capacitance is greatly changed depending on a stacking direction, and a change in the equivalent series inductance causes a great change (A→B) in a secondary resonance point. Therefore, the multilayered common mode filter according to the related art has a different common mode attenuation band depending on the mounting direction of a chip.

The multilayered common mode filter according to the embodiment of the present disclosure is formed in an LC filter structure (i.e., an LPF filter structure) in which the capacitor layers are arranged on the top and bottom of the electrode stack. Accordingly, the multilayered common mode filter according to the embodiment of the present disclosure has a small change in an equivalent series inductance of a parallel capacitance even though a stacking direction is changed. Accordingly, the multilayered common mode filter according to the embodiment of the present disclosure has a small change in a secondary resonance point and can form a common mode attenuation band at a constant level even though the mounting direction of a chip is changed.

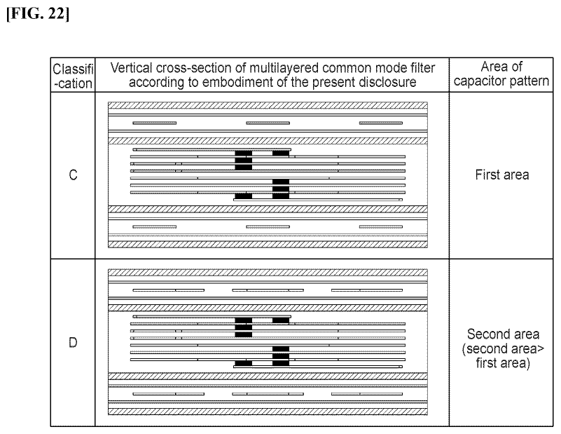

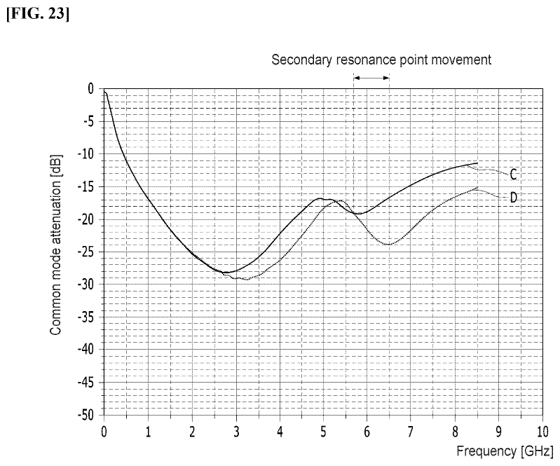

Referring to FIGS. 22 and 23, the multilayered common mode filter according to the embodiment of the present disclosure can adjust the secondary resonance point by changing the area of the capacitor pattern.

In the embodiment of the present disclosure, a multilayered common mode filter C including a capacitor pattern of a first area forms a secondary resonance point at approximately 5.5 GHz, and a multilayered common mode filter D including a capacitor pattern of a second area wider than the first area forms a secondary resonance point at approximately 6.5 GHz.

In this way, the multilayered common mode filter according to the embodiment of the present disclosure can move the secondary resonance point to a higher frequency by expanding the area of the capacitor pattern, and can move the secondary resonance point to a lower frequency by narrowing the area of the capacitor pattern.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A multilayered common mode filter comprising:
an upper electrode layer configured as a stacked body including a first coil pattern, a second coil pattern, and a third coil pattern;
a lower electrode layer configured as a stacked body including a fourth coil pattern, a fifth coil pattern, and a sixth coil pattern and arranged on a bottom of the upper electrode layer;
a first capacitor layer configured as a stacked body including a capacitor pattern and a ground pattern, arranged on a top of the upper electrode layer, and configured to overlap the first coil pattern to the sixth coil pattern to form an additional capacitance; and
a second capacitor layer configured as a stacked body including a capacitor pattern and a ground pattern, arranged on a bottom of the lower electrode layer, and configured to overlap the first coil pattern to the sixth coil pattern to form an additional capacitance.

2. The multilayered common mode filter of claim 1, wherein the upper electrode layer and the lower electrode layer constitute an electrode stack,
the electrode stack is configured so that the first coil pattern, the second coil pattern, the third coil pattern, the fourth coil pattern, the fifth coil pattern, and the sixth coil pattern are sequentially stacked,
the first coil pattern and the sixth coil pattern form a first coil constituting a first channel,
the second coil pattern and the third coil pattern are interposed between the first coil pattern and the sixth coil pattern to form a second coil constituting a second channel, and
the fourth coil pattern and the fifth coil pattern are interposed between the third coil pattern and the sixth coil pattern to form a third coil constituting a third channel.

3. The multilayered common mode filter of claim 1, wherein the upper electrode layer comprises:
a first sheet having a first surface on which a first terminal pattern and a second terminal pattern are spaced apart from each other;
a second sheet having a first surface on which the first coil pattern and a first via hole are arranged, and arranged on a bottom of the first sheet;
a third sheet having a first surface on which the second coil pattern is arranged, and arranged on a bottom of the second sheet; and
a fourth sheet having a first surface on which the third coil pattern is arranged, and arranged on a bottom of the third sheet.

4. The multilayered common mode filter of claim 3, wherein the first coil pattern is arranged on the first surface of the second sheet, is interposed between the first sheet and the second sheet, and is connected to the sixth coil pattern to form a first channel,
a first end of the first coil pattern is connected to a first end of the first terminal pattern, and
a second end of the first coil pattern is arranged on the same line as a second side of the second sheet opposite to a first side of the second sheet.

4. The multilayered common mode filter of claim 3, wherein the second coil pattern is arranged on the first surface of the third sheet, and is interposed between the second sheet and the third sheet,
a first end of the second coil pattern is connected to a first end of the second terminal pattern through the first via hole, and
a second end of the second coil pattern is arranged on the same line as a second side of the third sheet opposite to a first side of the third sheet.

6. The multilayered common mode filter of claim 3, wherein the third coil pattern is arranged on the first surface of the fourth sheet, and is interposed between the third sheet and the fourth sheet,
a first end of the third coil pattern is connected to a first end of the second terminal pattern, and
a second end of the third coil pattern is arranged on the same line as a second side of the fourth sheet opposite to a first side of the fourth sheet.

7. The multilayered common mode filter of claim 3, wherein a first end of the first terminal pattern is arranged adjacent to a center of the first sheet and connected to a first end of the first coil pattern, a second end of the first terminal pattern is arranged on the same line as a first side of the first sheet,
a first end of the second terminal pattern is arranged adjacent to the center of the first sheet and connected to a first end of the second coil pattern through the first via hole, and a second end of the second terminal pattern is arranged on the same line as the first side of the first sheet.

8. The multilayered common mode filter of claim 1, wherein the lower electrode layer comprises:
a fifth sheet having a first surface on which the fourth coil pattern is arranged and arranged on the bottom of the upper electrode layer;
a sixth sheet having a first surface on which the fifth coil pattern is arranged, and arranged on a bottom of the fifth sheet;
a seventh sheet having a first surface on which the sixth coil pattern and a second via hole are arranged, and arranged on a bottom of the sixth sheet; and
an eighth sheet having a first surface on which a third terminal pattern and a fourth terminal pattern are spaced apart from each other.

9. The multilayered common mode filter of claim 8, wherein the fourth coil pattern is arranged on the first surface of the fifth sheet and interposed between the upper electrode layer and the fifth sheet,
a first end of the fourth coil pattern is arranged adjacent to a center of the fifth sheet and connected to a first end of the fifth coil pattern, and
a second end of the fourth coil pattern is arranged on the same line as a second side of the fifth sheet opposite to a first side of the fifth sheet.

10. The multilayered common mode filter of claim 8, wherein the fifth coil pattern is arranged on the first surface of the sixth sheet and interposed between the fifth sheet and the sixth sheet,
a first end of the fifth coil pattern is arranged adjacent to a center of the sixth sheet, is connected to a first end of the fourth coil pattern, and is connected to a first end of the third terminal pattern through the second via hole, and
a second end of the fifth coil pattern is arranged on the same line as a second side of the sixth sheet opposite to a first side of the sixth sheet.

11. The multilayered common mode filter of claim 8, wherein the sixth coil pattern is arranged on the first surface of the seventh sheet and interposed between the sixth sheet and the seventh sheet,
a first end of the sixth coil pattern is arranged adjacent to a center of the sixth sheet, is connected to a first end of the fourth coil pattern, and is connected to a first end of the third terminal pattern through the second via hole, and
a second end of the sixth coil pattern is arranged on the same line as a second side of the seventh sheet opposite to a first side of the seventh sheet.

12. The multilayered common mode filter of claim 8, wherein a first end of the third terminal pattern is arranged adjacent to a center of the eighth sheet and connected to a first end of the fifth coil pattern through the second via hole, a second end of the third terminal pattern is arranged on the same line as a first side of the eighth sheet,
a first end of the fourth terminal pattern is arranged adjacent to the center of the eighth sheet and connected to a first end of the sixth coil pattern, and a second end of the fourth terminal pattern is arranged on the same line as the first side of the eighth sheet.

13. The multilayered common mode filter of claim 1, wherein two or less via holes are formed in each of a plurality of sheets constituting the upper electrode layer and the lower electrode layer.

14. The multilayered common mode filter of claim 1, wherein the first capacitor layer and the second capacitor layer each comprise:
a ninth sheet having a first surface on which the ground pattern is arranged and arranged on a bottom of the lower electrode layer; and
a tenth sheet having a first surface on which the capacitor pattern is arranged and arranged on a bottom of the ninth sheet,
wherein the capacitor pattern is configured to overlap a coil pattern included in an electrode stack, in which the upper electrode layer and the lower electrode layer are stacked, to form an additional capacitance.

15. The multilayered common mode filter of claim 14, wherein the ground pattern comprises:
a first ground pattern formed in a plate shape and arranged on a first surface of the ninth sheet, with an outer periphery spaced apart from an outer periphery of the ninth sheet;
a second ground pattern having a first end connected to the first ground pattern and a second end arranged on the same line as a third side of the ninth sheet; and
a third ground pattern arranged to face the second ground pattern with the first ground pattern interposed therebetween, and having a first end connected to the first ground pattern and a second end arranged on the same line as a fourth side of the ninth sheet opposite to the third side of the ninth sheet.

16. The multilayered common mode filter of claim 14, wherein the capacitor pattern comprises:
a first capacitor pattern arranged on an upper surface of the tenth sheet;
a second capacitor pattern arranged on the upper surface of the tenth sheet to be spaced apart from the first capacitor pattern;
a third capacitor pattern arranged on the upper surface of the tenth sheet to be spaced apart from the first capacitor pattern and the second capacitor pattern;
a fourth capacitor pattern arranged on the upper surface of the tenth sheet to face the first capacitor pattern;
a fifth capacitor pattern arranged on the upper surface of the tenth sheet to be spaced apart from the fourth capacitor pattern and to face the second capacitor pattern; and
a sixth capacitor pattern arranged on the upper surface of the tenth sheet, to be spaced apart from the fourth capacitor pattern and the fifth capacitor pattern, and to face the third capacitor pattern,
wherein first ends of the first capacitor pattern to the third capacitor pattern are arranged on the same line as one of first and second sides of the tenth sheet, and
first ends of the fourth capacitor pattern to the sixth capacitor pattern are arranged on the same line as the other of the first and second sides of the tenth sheet.

17. The multilayered common mode filter of claim 14, wherein the capacitor layer is configured so that a plurality of ground patterns and a plurality of capacitor patterns are alternately stacked.

18. The multilayered common mode filter of claim 1, wherein the upper electrode layer, the lower electrode layer, the first capacitor layer, and the second capacitor layer constitute a filter stack, and the multilayered common mode filter further comprises:
a first external electrode arranged on a second side of the filter stack and connected to the first coil pattern and the sixth coil pattern that are exposed to a second side of the filter stack;
a second external electrode arranged on the second side of the filter stack and connected to the second coil pattern and the third coil pattern that are exposed to the second side of the filter stack;
a third external electrode arranged on the second side of the filter stack while being opposite to the second external electrode with the first external electrode interposed therebetween, and connected to the fourth coil pattern and the fifth coil pattern that are exposed to the second side of the filter stack;
a fourth external electrode arranged on a first side of the filter stack opposite to the second side of the filter stack and connected to the first terminal pattern and the fourth terminal pattern that are exposed to the first side of the filter stack;
a fifth external electrode arranged on the first side of the filter stack and connected to the second terminal pattern exposed to the first side of the filter stack;
a sixth external electrode arranged on the first side of the filter stack while being opposite to the fifth external electrode with the fourth external electrode interposed therebetween, and connected to the third terminal pattern exposed to the first side of the filter stack;
a seventh external electrode arranged on a third side of the filter stack and connected to a first end of the ground pattern exposed to the third side of the filter stack; and
an eighth external electrode arranged on a fourth side of the filter stack opposite to the third side of the filter stack and connected to a second end of the ground pattern exposed to the fourth side of the filter stack.
